(19) United States
(12) Patent Application Publication
(10) Pub. No.: US 2010/0206623 A1
(43) Pub. Date: Aug. 19, 2010

(54) NONCONDUCTIVE ADHESIVE COMPOSITION AND FILM AND METHODS OF MAKING

(76) Inventors: Kohichiro Kawate, Tokyo (JP); Hiroko Arita, Kanagawa (JP); Hideaki Yasui, Kanagawa (JP); Yoshiaki Sato, Kanagawa (JP)

Correspondence Address: 3M INNOVATIVE PROPERTIES COMPANY, PO BOX 33427, ST. PAUL, MN, 55133-3427, US

(21) Appl. No.: 12/682,333

(22) PCT Filed: Oct. 6, 2008
(86) PCT No.: PCT/US08/78936

§ 371 Date: Apr. 9, 2010

(30) Foreign Application Priority Data
Oct. 15, 2007 (JP) 2007-268149

(51) Int. Cl. H05K 1/02; C08L 63/00; B32B 38/10

(52) U.S. Cl. 174/259; 523/400; 523/439; 156/155

(57) ABSTRACT

To provide a nonconductive adhesive film, for electrically connecting a flexible printed circuit board to a circuit board, which is superior in both storage stability and curability and which suppresses the formation of air bubbles at the time of press bonding. A nonconductive adhesive film substantially comprising a heat-curable epoxy resin, a latent curing agent, and organic elastic fine particles of an average particle size of approximately 1 μm or less, a film being formed by aggregation of the organic elastic fine particles, is provided.

### TECHNICAL FIELD

The present disclosure relates to a nonconductive adhesive composition and nonconductive adhesive film and to methods of production and methods of use of the same. More particularly, the present disclosure relates to a nonconductive adhesive composition and nonconductive adhesive film placed between a flexible printed circuit board (FPC) and circuit board and capable of forming electric connections between their conductors by thermocompression bonding and methods of production and methods of use of the same.

### BACKGROUND

For the electrical connections of the glass boards and flexible printed circuit boards (FPC) of flat panel displays and the electrical connections of printed circuit boards and FPCs, anisotropic conductive films (ACF) have been used in the past. An ACF generally contains a heat-curable resin and conductive particles. By sandwiching an ACF between such circuit boards or boards and thermocompression bonding them, the conductive particles sandwiched between the conductors on one circuit board or board and the conductors on the other circuit board or board form electrical connections between these conductors. FIG. 1 is a cross-sectional view of an FPC 1 and glass board 4 where an ACF is used to form electrical connections between the conductors 2 on the FPC and the conductors 3 on the glass board. FIG. 1 shows that the conductors 2 and conductors 3 are electrically connected through conductive particles 6 dispersed in the heat-curable resin 5 of the ACF and that the conductive particles 6 are pressed between the conductors and deformed.

Along with the increasingly smaller size of electronic devices, recently the interconnect patterns of the above-mentioned circuit boards or boards have become higher in density. When using an ACF to form electrical connections between circuit boards or boards having such higher density interconnect patterns, the pitch between conductors becomes extremely small, so the conductive particles may short-circuit adjoining conductors on the same circuit boards or boards. Further, the conductive particles include very expensive metals etc., so the cost of the materials as a whole rises and as a result the production costs sometimes end up increasing.

As a method giving rise to results similar to an ACF, but using a material not containing any conductive particles, a nonconductive adhesive (NCA) has been proposed (H. Kristiansen and A. Bjorneklett, “Fine-pitch connection to rigid substrate using non-conductive epoxy adhesive”, J. Electronics Manufacturing, vol. 2, pp. 7-12, 1992). This method places a heat-curable resin between an FPC and circuit board or board and cures the heat-curable resin under pressure whereby the conductors on the FPC and the conductors on the circuit board or board are held in a press bonded state. This type of method does not use any expensive conductive particles, so short circuits will not occur even with fine interconnect connections and there are cost advantages as well, so a great improvement can be expected in the production process of liquid crystal displays, plasma displays, etc. FIG. 2 is a cross-sectional view of an FPC 1 and glass board 4 where an NCA is used to form electrical connections between conductors 2 on the FPC and conductor 3 on the glass board. FIG. 2 shows that the conductors 2 and conductors 3 are physically brought into direct contact and electrically connected and that the heat-curable resin 7 holds the conductors 2 and conductors 3 in a press bonded state.

However, this method continues to have various problems in practical application. When using the nonconductive adhesive film (NCF) method in which a nonconductive adhesive is formed in a film shape, it is preferable that the resin forming the NCF be removed from between these conductors and the surfaces of the press bonded conductors plastically deform. By the fine surface roughness on the surfaces of the conductors plastically deforming, electrical connections can be formed between these conductors even without any conductive particles. Therefore, to use the NCF method to form better electrical connections, press bonding the FPC by a relatively high pressure is preferable. The deflection of the base film of the FPC occurring at this time tends to become greater than the case of use of the ACF method.

The deflection occurring at the FPC at the time of thermocompression bonding has residual stress, so when releasing the load and cooling at the time of press bonding, the FPC will attempt to return to its original shape and air bubbles will sometimes form in the resin. FIG. 3 shows the amount of deflection D occurring in the FPC and the air bubbles 8 formed in the resin. The air bubbles can expand upon heating. In addition, they sometimes contain moisture. Therefore, such air bubbles not only detract from the reliability of the connections between the circuit boards or boards, but also sometimes cause a drop in the reliability of the insulation between adjoining conductors on the same circuit boards or boards. Therefore, in the NCF method, which is inherently advantageous for electrical connection of high density interconnects, solution of the problem of air bubbles is very strongly demanded.

As one approach for reducing the deflection of the FPC by the NCF method, reducing the outflow of the resin at the parts forming the air bubbles, that is, the sections between adjoining conductors on the circuit boards or boards where there are no conductors may be mentioned. For example, if raising the viscosity of the resin under the thermocompression bonding conditions, the outflow of resin can be suppressed. However, if the viscosity of the resin under the thermocompression bonding conditions becomes too high, the resin may thinly remain at the interface between the conductors desired for formation of electrical connections and may become a cause of poor contact. Therefore, in the NCF method, at the time of thermocompression bonding, the viscosity of the resin at the parts electrically connecting the conductors is preferably low, but to suppress the formation of air bubbles, the viscosity of the resin at the other parts is preferably high.

On the other hand, if considering the productivity of the thermocompression bonding step, the thermocompression bonding time is preferably short. As one effective method for shortening the thermocompression bonding time, raising the heating temperature at the time of curing the heat-curable resin may be mentioned. However, for example, if heating to 200° C. or more, elongation and/or deformation of the FPC may occur. From the viewpoint of stabilization of the production process, such elongation and/or deformation are not preferable. Therefore, it is preferable to use a curing system with a high reactivity curing at a low temperature in a short time. On the other hand, if using such a high reactivity curing system, for example, when stored at room temperature, the heat-curable resin will gradually cure along with the elapse of time, the viscosity characteristics of the material will change, and the desired viscosity characteristics will not be able to be obtained at the time of actual use in some cases.

As one effective method for achieving both the contradictory demands of fast curability and storage stability, the use of an encapsulated curing agent is known. This is a material comprised of an imidazole derivative or other curing agent with a high reactivity with epoxy covered by a thin film of a cross-linked polymer. By using such a material, an extremely excellent storage stability can be achieved. However, at the time of preparation of an NCF, the high polarity solvent such as methyl ethyl ketone (MEK) normally used for dissolving the thermoplastic resin or other polymer material ends up dissolving part of the encapsulating material covering the curing agent. Therefore, if using a solvent with a high dissolution ability at the time of preparation of an NCF, sometimes the encapsulated curing agent will not be able to exhibit sufficient latency and the storage stability of the NCF will be impaired.

Asai et al., J. Appl. Polym. Sci., Vol. 56, 769-777 (1995), describes that by dissolving an epoxy resin, phenoxy resin, microencapsulated imidazole, and conductive particles in a toluene/MEK mixed solvent and forming a film, fast curability and storage stability can both be achieved to a certain extent. In this document, the fact that the polar solvent MEK impairs the latency of microencapsulated imidazole is also found. J. Y. Kim et al., J. Mat. Processing Technology, Vol. 152, 357-362 (2004), describes dissolving an epoxy resin, NBR, microencapsulated imidazole, and conductive particles in toluene to prepare an ACF. However, when using such an ACF, it was discovered that aging at 85° C. and RH85% for 1000 hours resulted in the contact resistance increasing by 2Ω or more. Japanese Patent Publication (A) No. 10-21740 describes an ACF composition containing microencapsulated imidazole. This composition uses a film formation agent comprised of a phenoxy resin, urethane resin, SBR resin, polyvinyl butyral resin, polyester resin, etc. Japanese Patent Publication (A) No. 2006-252980 describes an ACF composition comprised of a reactive elastomer, epoxy resin, and latent curing agent (microencapsulated imidazole). Japanese Patent Publication (A) No. 2004-315688 describes a semiconductor production film comprised of a phenoxy resin having a fluorene skeleton, epoxy resin, and latent curing agent (microencapsulated imidazole). Japanese Patent Publication (A) No. 10-204153 describes an adhesive composition comprised of an epoxy resin having a naphthalene skeleton, liquid acrylic resin, and a latent curing agent (microencapsulated imidazole). Japanese Patent No. 3449904 describes a resin composition comprised mainly of trimethylol propane triacrylate, a bisphenol F type epoxy resin precursor, and a latent curing agent (microencapsulated imidazole). Japanese Patent No. 3883214 describes a resin composition comprised of an acrylic resin, epoxy resin, silica particles, and a latent curing agent (microencapsulated imidazole). Japanese Patent Publication (A) No. 5-32799 describes an ACF composition comprised of a reactive elastomer in which a silane coupling agent is uniformly mixed, an epoxy resin, and latent curing agent (microencapsulated imidazole). Japanese Patent Publication (A) No. 9-150425 describes an ACF composition comprised of a polyvinyl butyral resin, epoxy resin, and latent curing agent (microencapsulated imidazole). Japanese Patent Publication (A) No. 2006-73397 describes an ACF composition comprised of a solid epoxy resin and a latent curing agent (microencapsulated imidazole). Japanese Patent No. 3465276 describes an adhesive composition comprised of an acryl elastomer, epoxy resin, and latent curing agent (microencapsulated imidazole).

### SUMMARY

The present disclosure provides a nonconductive adhesive film consisting essentially of a heat-curable epoxy resin, a latent curing agent, and organic elastic fine particles of an average particle size of approximately 1 μm or less. The film is formed by aggregation of the organic elastic fine particles.

In one embodiment of the present disclosure, the organic elastic fine particles may be included at 40 to 90 wt % based on the solid content. In another embodiment, a material forming at least the surface of the organic elastic fine particles may have a Tg of room temperature or less. Further, in other embodiments, a material forming at least the surface of the organic elastic fine particles may include an acrylic resin and the organic elastic fine particles may include core-shell type elastic fine particles.

Further, in another embodiment, the latent curing agent may be an encapsulated curing agent and the encapsulated curing agent may include encapsulated imidazole.

Further, in another embodiment, the nonconductive adhesive film may have a modulus of elasticity of a value measured at 100° C. of 1.5×10⁻³ to 1.5×10⁻² times a value measured at room temperature. In another embodiment, the nonconductive adhesive film may have an apparent viscosity η, defined by η=σ/(dγ/dt) (where, η is an apparent viscosity, σ a shear stress, and dγ/dt a shear strain rate), of a value measured at 100° C. and a stress of 46.8 kPa of 4 times or more a value measured at 100° C. and a stress of 78.0 kPa. In a further embodiment, a flow rate after storage at room temperature for 2 weeks may be 90% to 110% of the initial flow rate.

Furthermore, the present disclosure provides a method of electrically connecting two circuit boards comprising the steps of preparing a first and second circuit board, each comprised of a circuit board provided with conductors, at least one of the circuit boards being a flexible printed circuit board, placing a nonconductive adhesive film as described above between the first and second circuit boards, and heating and pressing the first and second circuit boards between which the nonconductive adhesive film is placed so as to remove the nonconductive adhesive film between the conductors of the first and second circuit boards to electrically connect the conductors of the first circuit board and the conductors of the second circuit board and so as to cure the heat-curable epoxy resin.

Furthermore, the present disclosure provides an electronic device including circuit boards electrically connected by the above method. In one embodiment of the present disclosure, the electronic device is a flat panel display.

Further, the present disclosure provides a nonconductive adhesive composition consisting essentially of a heat-curable epoxy resin, a latent curing agent, organic elastic fine particles of an average particle size of approximately 1 μm or less, and a solvent capable of dispersing the organic elastic fine particles. The composition has film formability even without containing a polymer material dissolved in a solvent.

### BRIEF DESCRIPTION OF THE DRAWINGS

FIG. 1 is a lateral cross-sectional view of a prior art flexible printed circuit board and glass board electrically connected using an anisotropic conductive film.

FIG. 2 is a lateral cross-sectional view of a prior art flexible printed circuit board and glass board electrically connected using a nonconductive adhesive.

FIG. 3 is a lateral cross-sectional view of a prior art flexible printed circuit board and glass board electrically connected using a nonconductive adhesive where air bubbles form in the heat cured resin.

FIG. 4 is a scan type electron microscope photograph of a cured nonconductive adhesive film of an embodiment of the present disclosure.

FIG. 5 shows the Young's modulus of the adhesive film of Example 9 when not yet cured and after curing.

FIG. 6a is a photograph of a flexible printed circuit board thermocompression bonded using a sample of Example 1.

FIG. 6b is a photograph of a flexible printed circuit board thermocompression bonded using a sample of a comparative example.

FIG. 7 is a plot showing the relationship between the apparent viscosity and the amount of elastic fine particles.

FIG. 8 is a plot showing the relationship between the apparent viscosity and flow rate and the amount of elastic fine particles.

FIG. 9a is a schematic view showing the method of measurement of the contact resistance between a flexible printed circuit board and glass board.

FIG. 9b is a circuit diagram used when calculating the contact resistance.

### DETAILED DESCRIPTION OF THE PREFERRED EMBODIMENTS

The nonconductive adhesive composition of the present disclosure is characterized by the point of organic elastic fine particles being included and thereby having film formability even if not dissolving a polymer material in a solvent and incorporating it in the composition. This film formability is mainly provided by aggregation of the organic elastic fine particles. In the composition of the present disclosure, a solvent capable of dispersing the organic elastic fine particles is used, but this solvent is selected so as not to cause almost at all or not at all any harm to the latent curing agent. In the present disclosure, the polymer which was used in the past for forming a film is not required, so a solvent used to dissolve such a polymer material, but ending up causing harm to the latent curing agent, for example MEK, is not required. For this reason, the nonconductive adhesive composition of the present disclosure and the nonconductive adhesive film prepared using the composition can sufficiently exhibit the performances inherently possessed by a latent curing agent, that is, both the latency at ordinary temperature and the heat curing at the time of heating, and is extremely superior in storage stability.

Further, the mixture of the heat-curable epoxy resin and organic elastic fine particles forming the nonconductive adhesive film of the present disclosure is characterized by the point of enabling behavior as a pseudoplastic fluid in the molten state before heat curing. A “pseudoplastic fluid” means a fluid which exhibits behavior where the apparent viscosity becomes smaller if the stress acting on it becomes larger. For example, in one embodiment of the present disclosure, when measuring the viscosity at 100° C., the apparent viscosity measured at a stress of 46.8 kPa was four times or more the apparent viscosity measured at a stress of 78.0 kPa. By using a film including such a mixture, at the time of thermocompression bonding, the viscosity of the parts of the adhesive film electrically connecting the conductors, that is, the parts where stress is applied greater, becomes lower, the adhesive film is easily excluded from between the conductors, and electrical connections with small contact resistances can be formed. On the other hand, at parts where air bubbles may form, that is, at sections between adjoining conductors on a circuit board or board where there is no conductor, the applied stress becomes smaller, so the viscosity of the adhesive film is maintained higher, outflow of the adhesive film from those sections becomes smaller, and as a result the formation of air bubbles can be suppressed.

The above-mentioned description should not be construed as disclosing all of the embodiments of the present disclosure and all of the advantages or effects relating to the present disclosure. The present disclosure will be explained in further detail by the following drawings and detailed description for the purpose of illustrating a typical embodiment of the present disclosure.

The present disclosure provides a nonconductive adhesive composition consisting essentially of a heat-curable epoxy resin, a latent curing agent, organic elastic fine particles of an average particle size of approximately 1 μm or less, and a solvent capable of dispersing the organic elastic fine particles. This nonconductive adhesive composition has film formability even if not containing a polymer material dissolved in a solvent.

The heat-curable epoxy resin used in the present disclosure cures at the time of thermocompression bonding and bonds the FPC and circuit board. Further, the heat-curable epoxy resin also functions as a binder of the organic elastic fine particles in the adhesive composition or adhesive film of the present disclosure.

The heat-curable epoxy resin used in the present disclosure may include any epoxy resin known in this technical field, but as explained above, in order to function as a binder of the organic elastic fine particles, it is preferably liquid at ordinary temperature. Such a heat-curable epoxy resin preferably has a viscosity at 25° C. before curing of approximately 0.1 Pa·s or more, more preferably approximately 0.5 Pa·s or more, still more preferably approximately 1 Pa·s or more. Further, the viscosity at 25° C. before curing is preferably approximately 200 Pa·s or less, more preferably approximately 150 Pa·s or less, still more preferably approximately 100 Pa·s or less. The viscosity of the heat-curable epoxy resin may be measured using for example a Brookfield rotary viscometer.

As such an epoxy resin liquid at ordinary temperature, bisphenol type epoxy resins having an average molecular weight of approximately 200 to approximately 500 derived from epichlorohydrin and bisphenol A, F, AD, etc.; epoxy novolac resins derived from epichlorohydrin and phenol novolac or cresol novolac; naphthalene type epoxy resins having skeletons including naphthalene rings; various epoxy compounds having two or more glycidyl amine, glycidyl ether, and other glycidyl groups in a biphenyl, dichloropentadiene, or other molecule; alicyclic type epoxy compounds having two or more alicyclic epoxy groups in a molecule; and mixtures of two or more types of these may be used. Specifically, for example, Epicoat EP828 (bisphenol A type, epoxy equivalents: 190 g/eq, Japan Epoxy Resin), YD128 (bisphenol A type, epoxy equivalents: 184 to 194 g/eq, Tohto Kasei), Epicoat EP807 (bisphenol F type, Japan Epoxy Resin), EXA7015 (hydrated bisphenol A type, DIC), EP4088 (dicyclopentadiene type, Asahi Denka), HP4032 (naphthalene type, DIC), PLACCEL G402 (lactone-modified epoxy, epoxy equivalents: 1050 to 1450 g/eq, Daicel Chemical Industry), Celloxide (alicyclic type, Daicel Chemical Industry), etc. may be mentioned. The adhesive composition of the present disclosure may include one or more types of the above heat-curable epoxy resins mixed together.

The content of the heat-curable epoxy resin may be suitably selected by a person skilled in the art considering for example the type, structure, and molecular weight of the resin, the required bonding characteristics and curing characteristics, the type and content of the organic elastic fine particles, and, in addition, when the composition is used in the form of a film, the characteristics of the formed film (for example, flexibility etc.) If giving one example, the content of the heat-curable epoxy resin may be approximately 2 wt % or more with respect to the solid content of the adhesive composition, preferably approximately 5 wt % or more, more preferably approximately 15 wt % or more. Further, the content of the heat-curable epoxy resin may be approximately 60 wt % or less with respect to the solid content of the adhesive composition, preferably approximately 50 wt % or less, more preferably approximately 30 wt % or less.

The latent curing agent used in the present disclosure does not exhibit curability and does not cause the progression of the curing of the heat-curable epoxy resin included in the adhesive composition or adhesive film at ordinary temperature, but when heated exhibits curability and can cure the heat-curable epoxy resin to the desired level.

As the latent curing agent which can be used in the present disclosure, imidazole, hydrazide, trifluoroborane-amine complex, amineimide, polyamine, tertiary amine, alkylurea, or other amine compounds, dicyandiamide, and their modified products and mixtures of two or more of these may be mentioned.

Among the above-mentioned latent curing agents, imidazole latent curing agents are preferable. The imidazole latent curing agents include the imidazole latent curing agents known in this technical field, for example, adducts of imidazole compounds and epoxy resins. As such imidazole compounds, imidazole, 2-methyl imidazole, 2-ethylimidazole, 2-propyl imidazole, 2-dodecyl imidazole, 2-phenyl imidazole, 2-phenyl-4-methyl imidazole, and 4-methyl imidazole may be mentioned.

Furthermore, to enhance both the contradictory characteristics of storage stability and a fast curability, it is possible to use an encapsulated curing agent comprised of the above-mentioned latent curing agent as a core covered by a polyurethane-based, polyester-based, or other polymer substance or an Ni, Cu, or other metal thin film etc. as the latent curing agent of the present disclosure. Among such encapsulated curing agents, encapsulated imidazole is preferably used.

As this encapsulated imidazole, an imidazole-based latent curing agent comprised of an imidazole compound adducted by urea or an isocyanate compound and furthermore encapsulated by blocking its surface by an isocyanate compound or an imidazole-based latent curing agent comprised of an imidazole compound adducted by an epoxy compound and furthermore encapsulated by blocking its surface by an isocyanate compound may be mentioned. Specifically, for example, Novacure HX3941HP, Novacure HXA3042HP, Novacure HXA3922HP, Novacure HXA3792, Novacure HX3748, Novacure HX3721, Novacure HX3722, Novacure HX3088, Novacure HX3741, Novacure HX3742, Novacure HX3613 (all made by Asahi Kasei Chemicals), etc. may be mentioned. Note that Novacure is a product comprised of encapsulated imidazole and a heat-curable epoxy resin mixed together by a certain ratio.

Further, as the amine-based latent curing agent which can be used in the present disclosure, an amine-based latent curing agent known in this technical field may be included. A polyamine (for example, H-4070S, H-3731S, etc., ACR), tertiary amine (H3849S, ACR), alkylurea (for example, H-3366S, ACR), etc. may be mentioned.

The content of the latent curing agent may be approximately 1 wt % or more with respect to the weight of the heat curing epoxy resin, preferably is approximately 10 wt % or more, more preferably is approximately 15 wt % or more. Further, the content of the latent curing agent may be approximately 50 wt % or less with respect to the weight of the heat-curable epoxy resin, preferably approximately 25 wt % or less, more preferably approximately 21 wt % or less. Here, when using a commercially available mixture of a heat-curable epoxy resin and latent curing agent, note that the “content of the latent curing agent” indicates the ratio of the latent curing agent ingredient included in the mixture based on the total weight in the mixture of the heat-curable epoxy resin ingredient and other heat-curable epoxy resin ingredients. Further, the higher the reaction start temperature of the latent curing agent (also called the “activation temperature”), the higher the storage stability of the adhesive composition, while the lower the reaction start temperature, the faster the curing. To achieve both a fast curability and storage stability at as high levels as possible, the reaction start temperature of the latent curing agent is typically preferably approximately 50° C. or more, more preferably approximately 100° C. or more. Further, the reaction start temperature of the latent curing agent is preferably approximately 200° C. or less, more preferably approximately 180° C. or less. Here, the reaction start temperature of the latent curing agent (activation temperature) is defined as the temperature of the point where the tangent at the low temperature side temperature where the amount of generation of heat becomes ½ that of the peak intersects the baseline in a DSC (differential scan calorimeter) curve obtained when using a DSC with increasing the temperature from room temperature at 10° C./min using a mixture of a heat-curable epoxy resin and latent curing agent as a test sample.

The organic elastic fine particles are fine particles having elasticity at ordinary temperature. For example, the organic polymer forming the fine particles has a glass transition temperature of approximately −140° C. to room temperature in range. The organic elastic fine particles used in the present disclosure have small particle sizes, so when removing the solvent included in the adhesive composition, the fine particles tend to aggregate and form a film. If the particle size of the fine particles is large, the film flatness becomes lower and the possibility of inhibiting conduction between conductors becomes higher. When electrically connecting two conductors, the organic elastic fine particles present between the conductors have to be excluded from between the conductors or else be positioned at locations not affecting the electrical contacts of the conductors. A conductor surface typically has a surface roughness of approximately 1 to approximately 2 μm or so. If the organic elastic fine particles have an average particle size of approximately 1 μm or less, particles can be discharged into recesses in the conductor surface unlikely to form electrically contacting parts and the chance of affecting the electrical connections between conductors becomes lower. Therefore, the average particle size of the organic elastic fine particles used in the present disclosure is typically approximately 1 μm or less, preferably approximately 0.8 μm or less, more preferably approximately 0.6 μm or less. Further, the organic elastic fine particles have an average particle size of typically approximately 0.01 μm or more, preferably approximately 0.1 μm or more, more preferably approximately 0.3 μm or more.

As explained above, when forming a film, the elasticity of the organic elastic fine particles is believed to provide the strength and flexibility required by the film, so the Tg of the material forming at least the surface of the organic elastic fine particles is preferably room temperature or less, more preferably the Tg of all of the materials forming the organic elastic fine particles is room temperature or less (when the organic elastic fine particles are comprised of a plurality of materials).

The materials forming such organic elastic fine particles are for example well known in the technical field of shock modifiers. For example, acryl, methylmethacrylate-butadiene-styrene copolymer, acrylate-styrene-acrylonitrile copolymer, and other acrylic resins, acrylonitrile-butadiene-styrene copolymer, acrylonitrile-ethylenepropylene-styrene copolymer, high impact polystyrene (HIPS), and these mixtures or polymer alloys may be mentioned. When used for the adhesive composition of the present disclosure, the material forming the surface of the organic elastic fine particles preferably includes an acrylic resin, more preferably all materials forming the organic elastic fine particles include an acrylic resin (when the organic elastic fine particles are comprised of a plurality of materials). This is because the organic elastic fine particles including the acrylic resin are superior in dispersability with respect to a solvent compared with other materials.

As such an acrylic resin, for example, a radical polymerizable monomer including a (meth)acrylate monomer or an acrylic-based copolymer including a polyfunctional monomer may be mentioned. The radical polymerizable monomer may, if necessary, include another radical polymerizable monomer capable of copolymerizing with a (meth)acrylate monomer. As the (meth)acrylate monomer used, for example, ethyl acrylate, n-propyl acrylate, n-butyl acrylate, isobutyl acrylate, sec-butyl acrylate, n-hexyl acrylate, 2-ethylhexyl acrylate, n-octyl acrylate, isooctyl acrylate, isononyl acrylate, n-decyl acrylate, n-octyl methacrylate, n-nonyl methacrylate, n-decyl methacrylate, lauryl methacrylate, etc. may be mentioned. The radical monomer copolymerizable with a (meth)acrylate monomer may be a radical monomer known in this technical field which can polymerize with a (meth)acrylate monomer. For example, isoprene, vinyl acetate, a vinyl ester of a branched carboxylic acid, styrene, isobutylene, etc. may be mentioned. The polyfunctional monomer becomes the cross-linking points of the obtained acrylic-based copolymer and is used to control the unpreferable agglomeration of acrylic-based copolymer particles during production and after production. As such polyfunctional monomers, for example, ethyleneglycol di(meth)acrylate, diethyleneglycol di(meth)acrylate, triethyleneglycol di(meth)acrylate, 1,6-hexanediol di(meth)acrylate, trimethylol propane di(meth)acrylate, and other di(meth)acrylates; trimethylol propane tri(meth)acrylate, ethylene oxide modified trimethylol propane tri(meth)acrylate, pentaerithritol tri(meth)acrylate, and other tri(meth)acrylates may be mentioned. Further, as the other polyfunctional monomers, pentaerythritol tetra(meth)acrylate, dipentaerythritol hexa(meth)acrylate, allyl(meth)acrylate, diallyl phthalate, diallyl malate, diallyl fumarate, diallyl succinate, triallyl isocyanulate, and other di- or triallyl compounds, divinyl benzene, divinyl adipate, butadiene, and other divinyl compounds etc. may be mentioned. These polyfunctional monomers may be used combined in two or more types. By suspension polymerization or emulsion polymerization of the above compounds, fine particles can be obtained.

The organic elastic fine particles may also be so-called “core-shell type” elastic fine particles having shell parts and core parts. In general, the shell part is designed to have a Tg higher than the Tg of the core part. By using this kind of core-shell type elastic fine particles, the low Tg core parts act as points of concentration of stress, whereupon the formed film is given flexibility, while the shell parts control the undesirable agglomeration of fine particles, so the dispersability of the fine particles with respect to the solvent and heat-curable epoxy resin can be expected to rise.

As one example of such core-shell type elastic fine particles, acrylic-based core-shell type elastic fine particles with core parts of a copolymer including a (meth)acrylate and polyfunctional monomer and with shell parts comprised of a mixed monomer containing a (meth)acrylate and polyfunctional monomer which is graft copolymerized onto the outside of the core parts may be mentioned. In one example of the present disclosure, for example, the types and amounts of the (meth)acrylate and polyfunctional monomer are selected so that the copolymer forming the core parts has a Tg of approximately −140° C. to approximately −30° C. and the shell parts have a Tg of approximately −30° C. to approximately 150° C. By selecting this, the dispersability of elastic fine particles can be improved. The (meth)acrylate monomer and polyfunctional monomer may be the ones explained above for acrylic resins. Similarly, the other radical polymerizable monomer capable of copolymerizing with the above (meth)acrylate monomer may be included a core part and/or shell part. Further, a plurality of core parts with different compositions may be included in the core-shell type elastic fine particles. A multilayer shell structure where the core part is covered by a shell part and that shell part is covered by another shell part may also be given to the core-shell type elastic fine particles.

Such core-shell type elastic fine particles may, for example, be produced by using the conventionally known emulsion polymerization method, suspension polymerization method, etc. When a plurality of types of monomers are included, random copolymerization, block copolymerization, graft copolymerization, and any other suitable copolymerization may be used. As the method for forming the core-shell structure, a method known in this technical field may be used. For example, the above-explained polymerization method may be used to form the particles of the core parts and a monomer as explained above may be graft polymerized for forming the shell parts of those particles. The graft polymerization of the shell parts may also be performed continuously by a polymerization process the same as with the polymerization of the core parts.

The greater the content of the organic elastic fine particles, the higher the plastic fluidity of the adhesive film, the film formability, and the strength as a film that are possible. On the other hand, if the content of the organic elastic fine particles is reduced, the adhesive film can be improved in heat resistance and creep resistance. For example, the content of the organic elastic fine particles may be approximately 30 wt % or more with respect to the solid content of the adhesive composition, preferably approximately 40 wt % or more, more preferably approximately 55 wt % or more. Further, the content of the organic elastic fine particles may be approximately 95 wt % or less with respect to the solid content of the adhesive composition, preferably approximately 80 wt % or less, more preferably approximately 70 wt % or less. Here, the “solid content” indicates the total weight of the heat curing epoxy resin, organic elastic fine particles, and latent curing agent and, in other words, is the weight of the ingredients after removing the solvent from the adhesive composition.

The solvent capable of dispersing the above-mentioned organic elastic fine particles may be suitably selected so as to give the desired level of dispersion in accordance with the polarity of the surface functional groups of organic elastic fine particles, the type of polymer forming the organic elastic fine particles, and the average particle size of the organic elastic fine particles, but this solvent preferably does not dissolve the latent curing agent.

In selecting such a solvent, the dispersability of the organic elastic fine particles can be evaluated by measuring the change in secondary particle size of the dispersed particles over time using a particle size distribution measurement apparatus using the laser diffraction scattering method as the measurement principle (for example, LS-230, Beckman Coulter), a particle size distribution measurement apparatus using the dynamic light scattering method as the measurement principle (for example, “Nanotrack UPA”, Nikkiso), etc. The ability of a solvent to dissolve a latent curing agent can be evaluated by mixing the latent curing agent and solvent for evaluation of a suitable heat-curable epoxy resin, allowing the mixture to stand for a predetermined time if necessary, then using a DSC (differential scan calorimeter) to determine the exothermic peak of the mixture. By using the above evaluation method, a person skilled in the art could suitably select a solvent capable of being used for an adhesive composition in accordance with the targeted application. As the solvent, for example, xylene, toluene, hexane, heptane, octane, cyclohexane, or other hydrocarbons, dioxane and other ethers, ethyl acetate, isopropyl acetate, butyl acetate, isoamyl acetate, isobutyl acetate, and other esters and other organic solvents may be mentioned.

For example, when the organic elastic fine particles are acrylic core-shell type fine particles and the latent curing agent is encapsulated imidazole covered by a urethane-based material, as the above-mentioned solvent, ethyl acetate, isopropyl acetate, butyl acetate, isoamyl acetate, isobutyl acetate, and other ester-based solvents are preferably used since there is little adverse effect on the encapsulated imidazole. Ethyl acetate is a relatively low boiling point solvent and enables easy drying at the time of film formation, so is preferably used.

The content of the solvent, considering the desired viscosity of the adhesive composition, should be the amount required for dispersing the organic elastic fine particles. Approximately 100 parts by weight or more with respect to 100 parts by weight of solid content of the adhesive composition is preferable, while approximately 200 parts by weight or more is more preferable. Further, the content of the solvent is preferably approximately 1000 parts by weight or less with respect to 100 parts by weight of solid content of the adhesive composition, more preferably approximately 500 parts by weight or less.

A polymer material dissolved in a suitable solvent may be added to the nonconductive adhesive composition, for example to assist the film formability, as an optional ingredient. The “polymer material” is comprised of a thermoplastic resin or heat-curable resin known in this technical field and capable of giving an adhesive composition a film formability. Such a material typically is solid at room temperature or has an average molecular weight of 1000 or more. As such a thermoplastic resin, for example, phenoxy, polyester, polyurethane, polyimide, polybutadiene, polypropylene, polyethylene, styrene-butadiene-styrene copolymer, polyacetal, polyvinyl butyral, butyl rubber, chloroprene rubber, polyamide, acrylonitrile-butadiene copolymer, acrylonitrile-butadiene-methacrylic acid copolymer, acrylonitrile-butadiene-styrene copolymer, polyvinyl acetate, nylon, styrene-isoprene copolymer, styrene-butylene-styrene block copolymer, and these mixtures or polymer alloy may be mentioned. Further, as the heat-curable resin, for example, the above-mentioned types of epoxy resin having an average molecular weight of 1000 or more and solid at ordinary temperature may be mentioned. However, the types and amounts of the polymer material and solvent for dissolving the polymer material are desirably determined so that the solvent does not reduce the latency of the latent curing agent to an unpreferable level. The amount of the polymer material included in the adhesive composition is preferably approximately 0.1 wt % to approximately 5 wt % with respect to the total solid content of the adhesive composition. The adhesive composition not including any polymer material is most preferable. In this way, the adhesive composition of the present disclosure does not substantially require a polymer material for film formation and a solvent dissolving such a material, so the latency of the late curing agent is not harmed by such a solvent and the storage stability is superior. Further, the adhesive composition of the present disclosure may further have other additives etc. added to it in accordance with need.

The adhesive composition of the present disclosure may be produced by mixing the organic elastic fine particles, heat-curable epoxy resin, latent curing agent, and solvent using for example a high speed mixer etc. The order in which the different ingredients are mixed is not particularly limited, but to prevent the latent curing agent from being damaged by the mechanical mixing, the latent curing agent is preferably added at the end of the process. For example, the organic elastic fine particles may be dispersed in the solvent, then the heat-curable epoxy resin and latent curing agent mixed in the dispersion or the heat-curable epoxy resin may be premixed in the solvent, then the organic elastic fine particles dispersed in the mixture and the latent curing agent added. When the organic elastic fine particles secondarily aggregate, if necessary a beads mill etc. may be used to pulverize them before mixing.

The nonconductive adhesive film of the present disclosure can be formed by coating the nonconductive adhesive composition obtained in the above way on a substrate then removing the solvent included in the adhesive composition to form a film. As the substrate, a silicone-treated polyester film, a polytetrafluoroethylene or other resin film given a release property, stainless steel sheets covered by these resin films, etc. may be used. The nonconductive adhesive composition may be coated on the substrate using a knife coater, bar coater, screen printing, etc. The solid content and amount coated may be adjusted to form various thicknesses of film. The solvent may be removed by heating using an oven, hot plate, etc. to a temperature at which the latent curing agent will not activate, for example, approximately 100° C. or less.

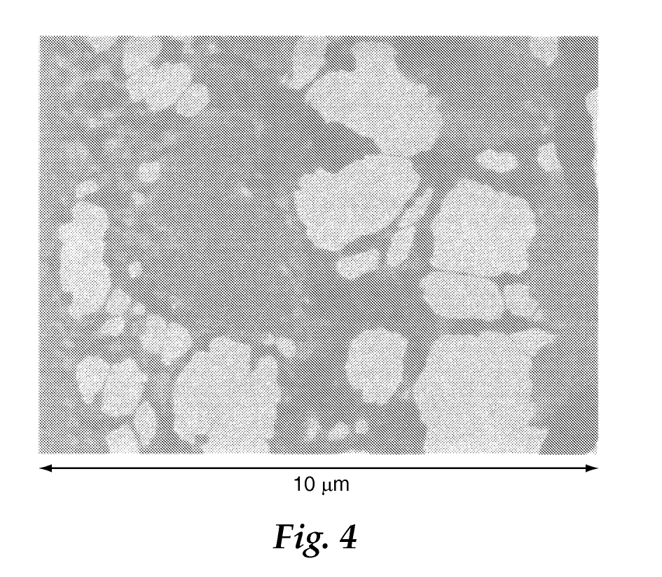

The nonconductive adhesive film of the present disclosure is substantially comprised of a heat-curable epoxy resin, a latent curing agent, and organic elastic fine particles of an average particle size of approximately 1 μm or less. When removing the solvent from the adhesive composition, the organic elastic fine particles aggregate whereby a film is formed. The heat-curable epoxy resin is present in the spaces between the aggregated organic elastic fine particles and functions as a binder for the organic elastic fine particles. Further, the latent curing agent, as explained above, is present in the film without impairing the latency. FIG. 4 is a photograph of a nonconductive adhesive film of one example of the present disclosure heat cured in a state without application of pressure and observed in lateral cross-section by a scanning electron microscope. The parts appearing white in FIG. 4 are parts where the organic elastic fine particles have detached at the time of cutting the adhesive film. The gray parts (in the figure, slightly to the left of the center and rising at a slight incline to the left from the center of the right end) are cross-sections of the cut organic elastic fine particles, while the parts appearing black are the cured epoxy resin phase. From this figure, it is learned that the organic elastic fine particles aggregate and form continuous phases.

The nonconductive adhesive film may be suitably selected in thickness, size, and shape in accordance with the thicknesses of the conductors to be electrically connected. As one example, in production of a general flat panel display, to electrically connect an FPC and circuit board, the nonconductive adhesive film desirably has a thickness of for example approximately 5 μm to approximately 1 mm, preferably approximately 10 μm to approximately 200 μm, more preferably approximately 20 μm to approximately 50 μm.

The nonconductive adhesive film of the present disclosure preferably has a modulus of elasticity of a value measured at 100° C. of approximately 1×10⁻³ times or more the value measured at room temperature (25° C.), more preferably approximately 1.5×10⁻³ times or more it. Further, the nonconductive adhesive film preferably has a modulus of elasticity of a value measured at 100° C. of approximately 5×10⁻² times or less the value measured at room temperature (25° C.), more preferably approximately 1.5×10⁻² times or less. The above-mentioned modulus of elasticity can be determined by measuring the Young's modulus of the nonconductive adhesive film using the dynamic viscoelasticity measurement method at a temperature where the adhesive film will not start to cure. The conventional nonconductive adhesive film using a polymer material for film formation, compared to the nonconductive adhesive film of the present disclosure, has a higher modulus of elasticity at room temperature and a lower modulus of elasticity at the time of heating, for example, at 100° C. The adhesive film of the present disclosure having a modulus of elasticity within the above-mentioned range is believed to be distinctive to the nonconductive adhesive film of the present disclosure using organic elastic fine particles as film formation elements.

Here, while not intending that any theory be bound to, the modulus of elasticity at 25° C. expresses the strength and flexibility at the time of storage and handling of the nonconductive adhesive film. The modulus of elasticity at 100° C. is believed to express the fluidity of the film before heat curing at the time of thermocompression bonding. The modulus of elasticity of the nonconductive adhesive film in one embodiment of the present disclosure, giving one example, is 1×10⁸ to 4×10⁸ MPa at room temperature and 6×10⁵ to 1.5×10⁶ MPa in range at 100° C. With a heat-curable epoxy resin alone, this modulus of elasticity cannot be obtained at room temperature, so the film is believed to be given strength and flexibility by the agglomeration of the organic elastic fine particles in the adhesive film. Further, the modulus of elasticity at 100° C. being in this range suggests that the adhesive film is provided with not only the fluidity required for the target application, but also pseudoplasticity as explained later in the section on apparent viscosity.

Further, since the nonconductive adhesive film of the present disclosure includes organic elastic fine particles, it can have a behavior where an increase in the shear stress leads to a drop in the apparent viscosity, that is, pseudoplasticity. The nonconductive adhesive film of the present disclosure has an apparent viscosity η, defined by η=σ/(dγ/dt) (where, η is the apparent viscosity, σ is the shear stress, and dγ/dt is the shear strain rate), of a value measured at 100° C. and a stress of 46.8 kPa of preferably three or more times the value measured at 100° C. and stress 78.0 kPa, more preferably 4 times or more. Due to this pseudoplasticity, if using the nonconductive adhesive film of the present disclosure, at the time of thermocompression bonding, the epoxy resin and organic elastic fine particles are easily discharged from between the conductors and a small contact resistance electrical connection can be formed, while the formation of air bubbles can be suppressed in the sections between adjoining conductors on the circuit board or board where there are no conductors.

Further, the nonconductive adhesive film of the present disclosure can be produced even without using a solvent dissolving the latent curing agent and possibly impairing its latency, so has superior storage stability compared with a conventional nonconductive adhesive film. The nonconductive adhesive film of the present disclosure preferably has a flow rate after storage at room temperature for 2 weeks of preferably approximately 80% to approximately 120% of the initial flow rate, more preferably approximately 90% to approximately 110%. This flow rate will be explained in detail in the following embodiment.

The nonconductive adhesive film of the present disclosure is, during use, for example placed between a flexible printed circuit board (FPC) provided with conductors and a circuit board provided with conductors, then is heated and pressed together with the flexible printed circuit board and circuit board. At this time, the nonconductive adhesive film between the conductors of the flexible printed circuit board and the conductors of the circuit board is removed and electrical connections are formed between the conductors of the flexible printed circuit board and the conductors of the circuit board. At the same time, the heat-curable epoxy resin is cured and the flexible printed circuit board and circuit board are bonded.

An embodiment of the method of use of the nonconductive adhesive film of the present disclosure will be explained below. The nonconductive adhesive film of the present disclosure is hot laminated with the FPC at for example 80 to 120° C. using a roller laminator etc. so as to contact the surface of the FPC where the conductors are arranged. Next, for example, the circuit board is placed on the stage of the pulse heat bonder or ceramic heat bonder with the surface with the conductors facing upward, the FPC is moved over it with the surface with the nonconductive adhesive film stacked on it facing downward, and a microscope is used to position the corresponding conductors of the FPC and circuit board. After this, thermocompression bonding is applied at a temperature of 150 to 200° C. and a pressure of 1 to 10 MPa for 1 to 30 seconds. At this time, it is also possible to apply ultrasonic waves to the press bonded parts to promote electrical connection between the conductors. The ultrasonic waves assist the fusion bonding of the conductor metals with each other and further give shear stress due to vibration to the adhesive film present near the press bonded parts, so the viscosity of the parts is believed to fall and the removal of the adhesive film from between the conductors to be facilitated. Further, in accordance with need, post curing may also be performed. Further, the nonconductive adhesive film may be used after being hot laminated with the circuit board or may be arranged between the circuit boards or boards at the time of electrical connection without being hot laminated to the FPC and circuit board. Alternatively, the nonconductive adhesive composition of the present disclosure may be directly coated on the FPC or circuit board in the liquid state then dried so as to directly form a film on the circuit board or board.

The nonconductive adhesive film or nonconductive adhesive composition of the present disclosure can be used to electrically connect FPC's and circuit boards to produce various electronic devices such as plasma displays, liquid crystal displays, and other flat panel displays, organic EL displays, notebook computers, mobile phones, digital cameras, digital video cameras, and other electronic device. In particular, the nonconductive adhesive film or nonconductive adhesive composition of the present disclosure is suitable for use for plasma displays, liquid crystal displays, and other flat panel displays.

### EXAMPLES

Below, representative examples will be explained in detail, but it is clear to a person skilled in the art that the following examples can be modified and changed within the scope of the claims of the present application.

The materials used in this example were as follows:

HX3941HP (epoxy resin 65 wt %, curing agent 35 wt %), HXA3042HP (epoxy resin 66 wt %, curing agent 34 wt %), HXA3922HP (epoxy resin 67 wt %, curing agent 33 wt %), HXA3792 (epoxy resin 65 wt %, curing agent 35 wt %) and HX3748 (epoxy resin 65 wt %, curing agent 35 wt %) are mixtures of microencapsulated latent curing agents and heat-curable epoxy resins made by Asahi Kasei Chemicals.

EXL2314 is core-shell type elastic fine particles having an acrylic rubber layer as cores and an acrylic resin as shells and having a primary particle size of 100 to 600 nm sold by Rohm and Haas Company under the brandname Paraloid®.

G402 is PLACCEL G (lactone-modified epoxy resin) made by Daicel Chemical Industries.

YD128 is a bisphenol A type epoxy resin (epoxy equivalents 184 to 194) made by Tohto Kasei.

1010 is a bisphenol A type epoxy resin (epoxy equivalents 3000 to 5000) made by Japan Epoxy Resin.

YD170 is a bisphenol F type epoxy resin (epoxy equivalents 160 to 180) made by Tohto Kasei.

YP50S is a phenoxy resin (brandname Pheno Tohto) made by Tohto Kasei.

Further, the FPC, rigid printed circuit board, and glass board used in this example are as follows:

(1) FPC 1

Size: 18 mm×20 mm

Material: polyimide (Espanex M), thickness 25 μm

Interconnects: width 75 μm, interconnect pitch 125 μm, interconnect height 18 μm, interconnect number 50

The interconnects were exposed from one short side of the FPC in the longitudinal direction to 3 mm. This was used as the connection part with another board etc.

(2) FPC 2

Size: 18 mm×25 mm

Material: polyimide (Espanex M), thickness 25 μm

Interconnects: width 100 μm, interconnect pitch 100 μm, interconnect height 18 μm, interconnect number 50

The interconnects were exposed from one short side of the FPC in the longitudinal direction to 3 mm. This was used as the connection part with another board etc.

(3) Rigid Printed Circuit Board

Size: 18 mm×28 mm×0.5 m

Material: glass epoxy FR4

Interconnects: width 100 μm, interconnect pitch 100 μm, interconnect height 18 μm, interconnect number 50

The interconnects were exposed from one short side of the FPC in the longitudinal direction to 3 mm. This was used as the connection part with another board etc.

(4) Glass Board

Size: 14 mm×14 mm×1.1 mm

One entire surface of the board was covered by an ITO vapor deposited film deposited to 0.15 μm

### Example 1 to Example 14

The compositions of the nonconductive adhesive films are shown in Table 1 and Table 2. Ethyl acetates of 250 to 450 parts by weight with respect to 100 parts by weight of solid content were prepared. Next, core-shell type elastic fine particles were placed in the ethyl acetates and the mixtures were sufficiently stirred at room temperature using a high speed mixer to make the core-shell type particles completely disperse in the ethyl acetate. After this, the heat-curable epoxy resins and latent curing agents were dissolved in these mixtures to prepare nonconductive adhesive compositions. These nonconductive adhesive compositions were applied to silicone-treated polyester films using a knife coater and dried in an oven set to 100° C. for 5 minutes to prepare test use nonconductive adhesive films having thicknesses of 15 μm and 30 μm.

TABLE 1
Compositions of Adhesive Films Including HX3941HP

| | HX3941HP | EXL2314 | G402 | YD128 | Solvent |
|---|---|---|---|---|---|
| Ex. 1 | 18 | 64 | 18 | 0 | 400 |
| Ex. 2 | 15 | 70 | 15 | 0 | 450 |
| Ex. 3 | 20 | 60 | 20 | 0 | 350 |
| Ex. 4 | 25 | 50 | 25 | 0 | 300 |
| Ex. 5 | 30 | 40 | 30 | 0 | 250 |
| Ex. 6 | 14 | 64 | 22 | 0 | 400 |
| Ex. 7 | 10 | 64 | 26 | 0 | 400 |
| Ex. 8 | 9 | 64 | 18 | 0 | 400 |
| Ex. 9 | 20 | 70 | 10 | 0 | 450 |
| Ex. 10 | 18 | 64 | 0 | 18 | 400 |

(Units: Parts by Weight)

TABLE 2
Compositions of Adhesive Films Including Encapsulated Imidazole
Other Than HX3941HP (Units: Parts by Weight)

| | Encapsulated | | | |
|---|---|---|---|---|
| | imidazole* | EXL2314 | G402 | Solvent |
| Ex. 11 | HXA3042HP | 64 | 18 | 400 |
| Ex. 12 | HXA3922HP | 64 | 18 | 400 |
| Ex. 13 | HXA3792 | 64 | 18 | 400 |
| Ex. 14 | HX3748 | 64 | 18 | 400 |

*All 18 parts by weight

### Comparative Example

As a composition similar to the one described in Asai et al., J. Appl. Polym. Sci., Vol. 56, 769-777 (1995), the composition shown in Table 3 was used to fabricate a nonconductive adhesive film. This composition was applied to a silicone-treated polyester film using a knife coater and dried in an oven set to 100° C. for 5 minutes to prepare a nonconductive adhesive film of a comparative example of a thickness of 30 μm.

TABLE 3
Composition of Adhesive Film of Reference Example

| | HX3941HP | 1010 | YD170 | YP50S | Toluene | MEK |
|---|---|---|---|---|---|---|
| Ref. Ex. | 22 | 22 | 28 | 22 | 90 | 50 |

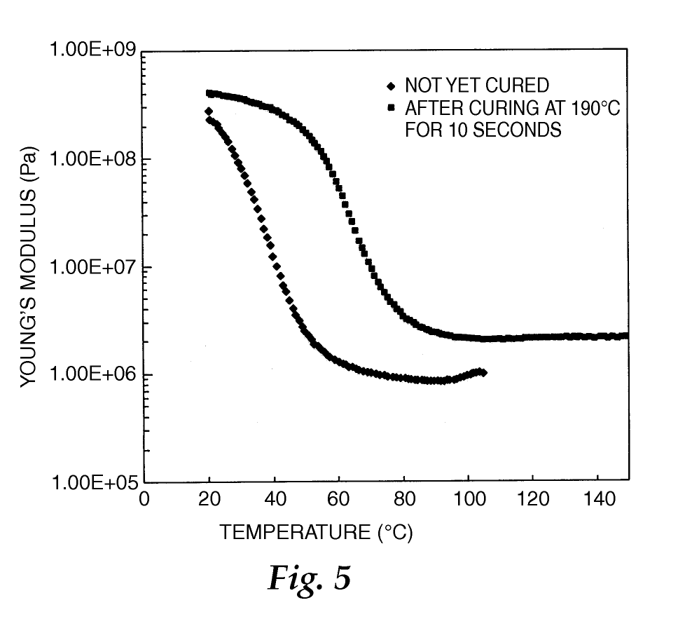

Measurement of Young's modulus of adhesive film: The adhesive film of Example 9 was measured for Young's modulus at the time when not yet cured and when cured, without applying pressure, at 190° C. for 10 seconds. The Young's modulus was measured as follows: A dynamic viscoelasticity apparatus RSA made by Rheotrix was used to measure the stored Young's modulus E′ (Young's modulus with respect to stress of same phase as strain in sinusoidal deformation) and the lost Young's modulus E″ (Young's modulus with respect to stress 90 degrees offset from phase of strain in sinusoidal deformation) at ω=6.28 rad/sec. The measurement was performed in the tensile mode for a film of a thickness of 60 μm. Note that for the measurement samples, two of thicknesses of 30 μm were laminated and used for measurement as 60 μm. The obtained results are shown in Table 4 and FIG. 5. The adhesive film of Example 9 had a Young's modulus at the time when not yet cured of 2.33×10⁸ Pa at 20° C. or not that much different from the Young's modulus after curing. This shows that the adhesive film of Example 9 has sufficient strength and flexibility even in the uncured state. Further, at the time of curing, the 100° C. Young's modulus was 9.64×10⁵ Pa. It was suggested that the adhesive film of Example 9 has fluidity controlled at the time of heating, that is, has pseudoplasticity.

TABLE 4
Young's Modulus of Adhesive Film of Example 9

| Temperature (° C.) | Not yet cured (Pa) | After curing at 190° C./10 sec |
|---|---|---|
| 20 | 2.33E+08 | 3.98E+08 |
| 30 | 8.18E+07 | 3.57E+06 |
| 40 | 1.21E+07 | 2.86E+06 |
| 50 | 2.25E+06 | 1.60E+06 |
| 60 | 1.27E+06 | 5.22E+06 |
| 70 | 1.02E+06 | 9.18E+06 |
| 80 | 9.07E+05 | 3.38E+06 |
| 90 | 8.52E+05 | 2.36E+06 |
| 100 | 9.64E+05 | 2.08E+06 |
| 110 | | 2.05E+06 |
| 120 | | 2.08E+06 |
| 130 | | 2.09E+06 |
| 140 | | 2.09E+06 |
| 150 | | 2.13E+06 |

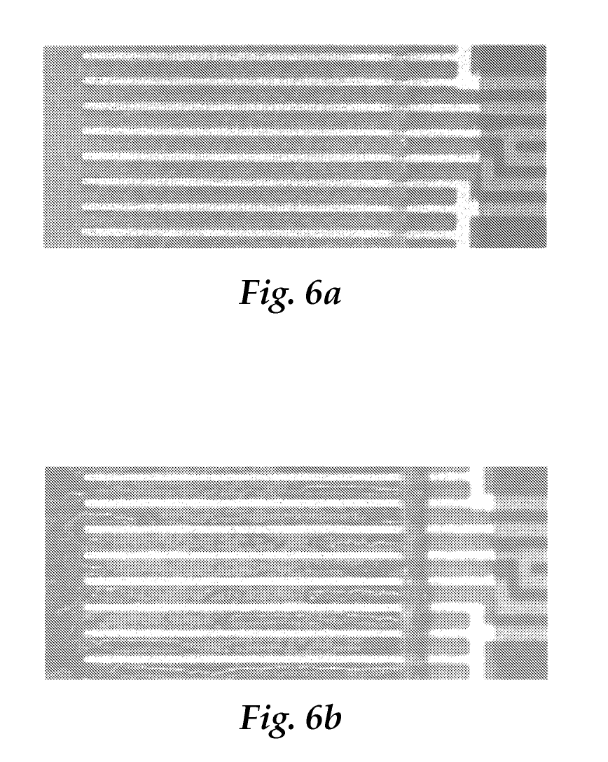

Observation of appearance: On a glass board of 14×14 mm² having an ITO vapor deposited film, an adhesive film of a thickness of 15 μm and dimensions of 2×14 mm² was placed. The FPC 1 was laid over the top of this, then the obtained laminate was thermocompression bonded. The thermocompression bonding was performed using an NA-75 made by Avionics, placing a 25 μm thick PTFE film between the laminate and NA-75 bonder head, and indirectly giving heat to the thermocompression bonding parts. The heat of the bonder head was adjusted so that the bonding parts were heated to a temperature of 180° C. for 15 seconds. The pressure at the time of the thermocompression bonding was 5 MPa. FIG. 6a and FIG. 6b are photographs showing a press bonded sample when observed from the glass board side. FIG. 6a is a photograph of a sample of Example 1, while FIG. 6b is a photograph of a sample of the comparative example. As shown in FIG. 6b, in the comparative example, the backing (polyimide) of the FPC was pushed at sections between adjoining conductors where no conductors are present. As a result, a large number of air bubbles were formed in these sections. The amount of deflection D of the polyimide was measured using a 3D noncontact surface shape measurement system (MM520N-M100 model) made by Ryoka Systems. The results are shown in Table 5. In Example 1, the amount of deflection D of the polyamide in the sections between conductors is clearly small and as a result it is believed the air bubbles become smaller.

TABLE 5
Amount of Deflection D of Adhesive Film of Example 1 (μm)

| | No. 1 | No. 2 | No. 3 | No. 4 | No. 5 | Average |
|---|---|---|---|---|---|---|
| Ex. 1 | 1.18 | 1.32 | 0.91 | 1.76 | 1.25 | 1.28 |
| Ref. ex. | 2.49 | 1.88 | 2.48 | 1.93 | 2.12 | 2.18 |

Evaluation of fluidity at time of thermocompression bonding: To quantitatively evaluate the fluidity of the adhesive film at the time of thermocompression bonding, the following procedure was followed to measure the flow rate (flow ratio) and the shear creep.

Flow rate: A film of a thickness of 30 μm was punched out into a disk shape of 6.1 mmφ. Between two glass boards of 30×30 mm² (thickness 1 mm), one drop of silicone oil was applied, then this disk shaped film sandwiched. This laminate was subjected to a force of 1370N for press bonding it at 180° C. for 10 seconds. In this embodiment, after 10 seconds, the film temperature reached an actually measured value of 193° C. The press bonded film substantially retained its circular shape and only became larger in diameter, so the value of the measured diameter after press bonding divided by the initial diameter is defined as the “flow rate”. This flow rate is believed to express the fluidity of the film at the time of thermocompression bonding.

Shear creep: Two polyimide films (thickness 75 μm) of 10×30 mm² were overlaid at their short sides. The overlaid parts were made lengths of 3, 5, and 7 mm. In the overlaid parts as a whole, adhesive films (thickness 30 μm) were sandwiched. These were thermocompression bonded at 100° C. for 1 second so as to prepare lap shear test pieces. A load of 234 g was applied to the two sides of these test pieces and the shear deformation of the bonded parts was measured. During the measurement, to eliminate as much as possible the effect of the resin curing and increasing the viscosity, the measurement was conducted at 100° C. The apparent viscosity=σ/(dγ/dt) was calculated from the shear strain rate dγ/dt=(shear rate)/(adhesive thickness), stress σ=(load)/(area of overlapped part).

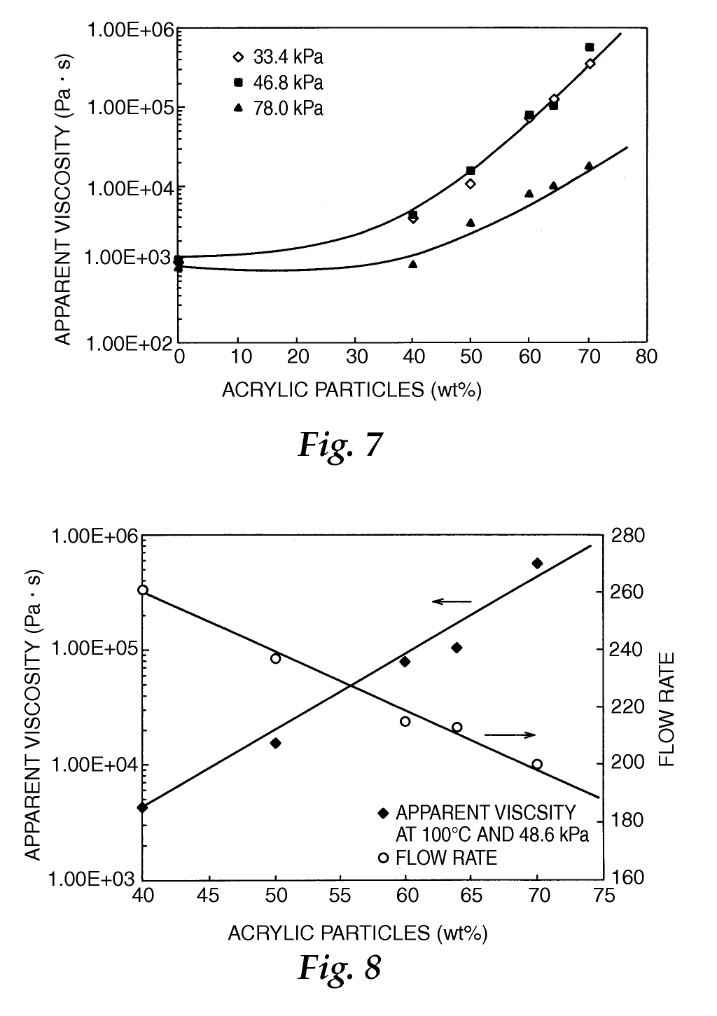

The apparent viscosity obtained using the above-mentioned method is shown in Table 6. Here, the adhesive thickness is the thickness of the adhesive film before the thermocompression bonding. FIG. 7 plots the apparent viscosity obtained by calculation with respect to the amount of the elastic fine particles (acrylic particles). For a system containing acrylic particles in an amount of 40 wt % or more, the apparent viscosity measured when the stress is 46.8 kPa is 4 to 10 times greater than the apparent viscosity measured in the case of 78.0 kPa. This shows that a mixture of acrylic particles and a heat-curable epoxy resin behaves completely as a pseudoplastic liquid before heat curing.

TABLE 6
Apparent Viscosities of Adhesive Films of
Examples 1 to 5 and Reference Example

| | Core-shell | | | | |
|---|---|---|---|---|---|
| | elastic fine | Viscosity | | | σ (46.8 kPa)/ |
| | particles (wt %) | σ (33.4 kPa) | σ (46.8 kPa) | σ (78.0 kPa) | σ (78.0 kPa) |
| Ex. 1 | 64 | 1.28E+05 | 1.04E+05 | 1.01E+05 | 10.3 |
| Ex. 2 | 70 | 3.53E+05 | 5.71E+05 | 1.81E+05 | 31.6 |
| Ex. 3 | 60 | 7.11E+04 | 7.89E+04 | 7.96E+05 | 9.9 |
| Ex. 4 | 50 | 1.05E+04 | 1.55E+04 | 3.40E+05 | 4.6 |
| Ex. 5 | 40 | 3.80E+03 | 4.25E+03 | 1.00E+05 | 4.2 |
| Ref. ex. | 0 | 1.01E+03 | 1.15E+03 | 9.39E+05 | 1.2 |

(Unit: Pa-s)

FIG. 8 plots the apparent viscosities measured for samples of Example 1 to 5 at 100° C. and 46.8 kPa and the flow rates measured by the above-mentioned method with respect to the weight percentages of the acrylic particles.

Storage stability: Table 7 shows the initial flow rates of samples measured by the above-mentioned method and the flow rates measured after aging the samples in an environment of 30° C. and RH70% for 1 week and 2 weeks.

TABLE 7
Flow Rates at Initial Period and After 1 Week and 2 Week Aging (%)

| | Initial | After 1 week | After 2 weeks |
|---|---|---|---|
| Ex. 1 | 213 | 206 | 208 |
| Ex. 2 | 200 | 195 | 195 |
| Ex. 3 | 215 | 211 | 210 |
| Ex. 4 | 230 | | |
| Ex. 5 | 237 | | |
| Ex. 6 | 191 | 179 | 185 |
| Ex. 7 | 224 | 225 | 223 |
| Ex. 8 | 238 | | |
| Ex. 10 | 191 | | |
| Ex. 11 | 213 | | |
| Ex. 12 | 217 | | |
| Ex. 13 | 224 | 220 | 217 |
| Ex. 14 | 213 | | |

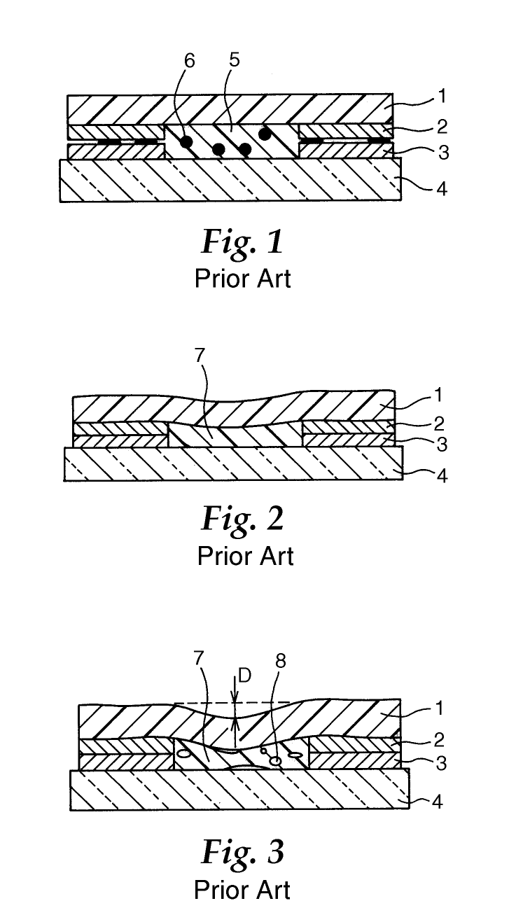

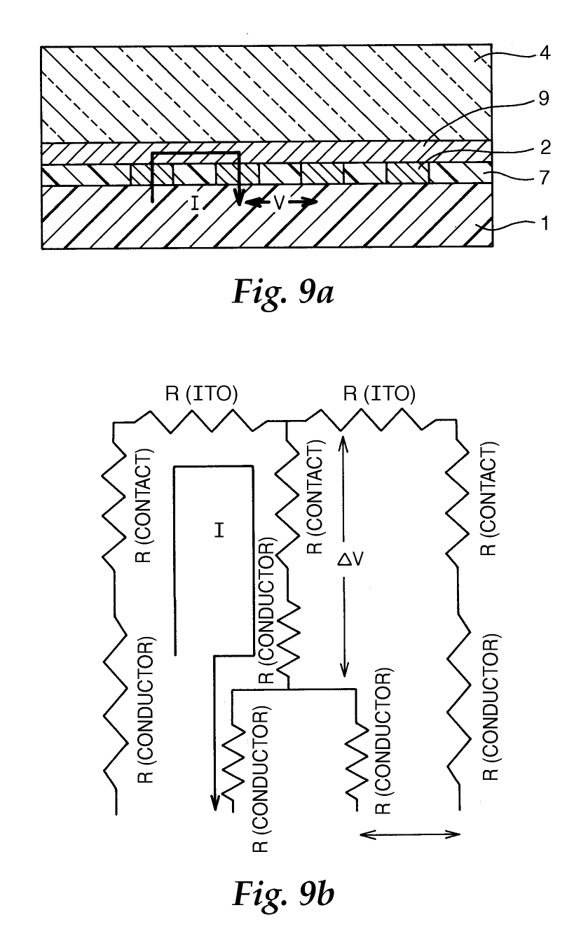

Electrical connection of FPC and glass board: A FPC 1 having a test use interconnect pattern shown in FIG. 6a and a glass board having an ITO vapor deposited film were connected using the adhesive film of each of Examples 1 to 7, Example 13, and the reference example. As shown in FIG. 9a, a current was applied and the voltage change ΔV of the contact parts was measured. The connection parts of the FPC and the glass board were overlaid by approximately 2 mm. Between the overlaid parts, an adhesive film of a thickness of 15 μm cut to 2×14 mm was sandwiched. A pressure of 3.5 MPa was applied and the assembly thermocompression bonded at 184° C. for 20 seconds. The numerals 1, 2, 4, and 7 in FIG. 9a are the same as those shown in FIGS. 1 to 3, while “9” indicates ITO. In the circuit diagram shown in FIG. 9b, the contact resistance was calculated by the approximation equation: V=ΔV=(R(contact)+R(conductor))×I≅R (contact)×I. Table 8 shows the change in the contact resistance when aging a sample at a high temperature and high humidity (60° C., RH90%). Further, the adhesive film of Example 1 was measured for change along with time of the contact resistance of samples prepared under various press forming conditions. The results are shown in Table 9.

Electrical connection of FPC and rigid printed circuit board: The connection of the FPC and rigid printed circuit board (FR4) was tested using the following method. An FPC 2 and a rigid printed circuit board (FR4) were prepared. The conductors of the parts for connecting the FR4 and FPC were made of a base of Ni plated with gold. By connecting the FR4 and FPC conductors, a chain circuit connected at 50 locations was formed. The chain circuit had a resistance value, combined with the bulk resistance of the interconnects themselves, of approximately 3Ω. An adhesive film of a thickness of 30 μm, a width of 2 mm, and a length of 12 mm was laid over the conductors of the rigid printed circuit board in advance. The connection parts of the FPC are overlaid by 2 mm with the connection parts of the rigid printed circuit board and the conductors positioned with each other, then a soldering iron was used to provisionally fasten it on the rigid printed circuit board. A heat bonder was pressed against this from the FPC side to give heat and pressure so as to eject the film from between the conductors of the FPC and the conductors of the rigid printed circuit board and electrically connect the conductors and so as to cure the resin and bond the FPC and rigid printed circuit board. At the time of the thermocompression bonding, the pressure given to this connection part was 4 MPa. The heating was performed at 180° C. for 10 seconds. A sample prepared by this method was aged at a high temperature and high humidity (85° C., RH85%). The change in the contact resistance at that time was shown in Table 8 converted to each connection.

TABLE 8
Changes Along With Time in Contact Resistance of FPC and Glass
Board and Printed Circuit Board (After 1000 Hours Aging)

| | ΔR(Ω) | ΔR(Ω) |
|---|---|---|
| | FPC/Glass board | FPC/Printed circuit board |
| Ex. 1 | 0.122 | 0.023 |
| Ex. 2 | 0.346 | 0.042 |
| Ex. 3 | 0.204 | 0.022 |
| Ex. 4 | 0.237 | 0.067 |
| Ex. 5 | 0.486 | 0.026 |
| Ex. 6 | 0.140 | 0.009 |
| Ex. 7 | 1.427 | |
| Ex. 13 | | 0.464 |
| Ref. ex. | 2.1 (500 hours) | |

TABLE 9
Changes Along With Time in Contact Resistance of FPC and
Glass Board Under Various Press Bonding Conditions

| Temp. | Pressure | Time | 300 | 500 | 850 | 1150 |
|---|---|---|---|---|---|---|
| (° C.) | (MPa) | (sec) | hours | hours | hours | hours |
| 190 | 5 | 5 | 0.200 | 0.317 | 0.499 | 0.580 |
| 190 | 3 | 5 | 0.158 | 0.208 | 0.282 | 0.364 |
| 200 | 3 | 5 | 0.132 | 0.241 | 0.342 | 0.705 |
| 180 | 3 | 5 | 0.330 | 0.332 | 0.470 | 0.745 |
| 180 | 5 | 5 | 0.107 | 0.229 | 0.380 | 0.472 |
| 200 | 5 | 10 | 0.158 | 0.248 | 0.318 | 0.560 |
| 190 | 5 | 5 | 0.188 | 0.362 | 0.517 | 0.571 |
| 190 | 3 | 5 | 0.079 | 0.115 | 0.099 | 0.169 |
| 190 | 3 | 10 | 0.112 | 0.209 | 0.287 | 0.734 |

1. A nonconductive adhesive film consisting essentially of
a heat-curable epoxy resin,
a latent curing agent, and
organic elastic fine particles of an average particle size of approximately 1 μm or less, wherein the film is formed by aggregation of said organic elastic fine particles.

2. A nonconductive adhesive film as set forth in claim 1 wherein said organic elastic fine particles are included at 40 to 90 wt % based on the solid content.

3. A nonconductive adhesive film as set forth in claim 1, wherein a material forming at least the surface of said organic elastic fine particles has a Tg of room temperature or less.

4. A nonconductive adhesive film as set forth in claim 1, wherein a material forming at least the surface of said organic elastic fine particles includes an acrylic resin.

5. A nonconductive adhesive film as set forth in claim 1, wherein said organic elastic fine particles include core-shell type elastic fine particles.

6. A nonconductive adhesive film as set forth in claim 1, wherein said latent curing agent is an encapsulated curing agent.

7. A nonconductive adhesive film as set forth in claim 6, wherein said encapsulated curing agent includes encapsulated imidazole.

8. A nonconductive adhesive film as set forth in claim 1, wherein said nonconductive adhesive film has a modulus of elasticity of a value measured at 100° C. of 1.5×10⁻³ to 1.5×10⁻² times a value measured at room temperature.

9. A nonconductive adhesive film as set forth in claim 1, wherein said nonconductive adhesive film has an apparent viscosity η, defined by η=σ/(dγ/dt) (where, η is an apparent viscosity, σ a shear stress, and dγ/dt a shear strain rate), of a value measured at 100° C. and a stress of 46.8 kPa of 4 times or more a value measured at 100° C. and a stress of 78.0 kPa.

10. A nonconductive adhesive film as set forth in claim 1, wherein a flow rate after storage at room temperature for 2 weeks is 90% to 110% of the initial flow rate.

11. A method of electrically connecting two circuit boards comprising the steps of:
preparing a first and second circuit board, each comprised of a circuit board provided with conductors, at least one of the circuit boards being a flexible printed circuit board,
placing a nonconductive adhesive film as set forth in claim 1 between said first and second circuit boards, and
heating and pressing said first and second circuit boards between which said nonconductive adhesive film is placed so as to remove said nonconductive adhesive film between said conductors of said first and second circuit boards to electrically connect said conductors of said first circuit board and said conductors of said second circuit board and so as to cure said heat-curable epoxy resin.

12. An electronic device including circuit boards electrically connected by the method as set forth in claim 11.

13. An electronic device as set forth in claim 12, wherein said electronic device is a flat panel display.

14. A nonconductive adhesive composition consisting essentially of
a heat-curable epoxy resin,
a latent curing agent,
organic elastic fine particles of an average particle size of approximately 1 μm or less, and
a solvent capable of dispersing said organic elastic fine particles, wherein the nonconductive adhesive composition has film formability even without containing a polymer material dissolved in a solvent.
